(19) United States
(12) Patent Application Publication
(10) Pub. No.: US 2012/0139109 A1
(43) Pub. Date: Jun. 7, 2012

(54) PRINTED CIRCUIT BOARD FOR SEMICONDUCTOR PACKAGE CONFIGURED TO IMPROVE SOLDER JOINT RELIABILITY AND SEMICONDUCTOR PACKAGE HAVING THE SAME

(75) Inventor: Jun-young CHOI, Seoul (KR)

(73) Assignee: Samsung Electronics Co., Ltd, Suwon-si (KR)

(21) Appl. No.: 13/310,925

(22) Filed: Dec. 5, 2011

(30) Foreign Application Priority Data
Dec. 6, 2010 (KR) 10-2010-0123730

(51) Int. Cl. H01L 23/498; H01L 21/56

(52) U.S. Cl. 257/738; 257/737; 438/127; 257/E23.069; 257/E23.068; 257/E21.504

(57) ABSTRACT

A a printed circuit board (PCB) for a semiconductor package and a semiconductor package having the same, which may improve adhesion of a PCB with an encapsulant. The semiconductor package includes a PCB for a semiconductor package including a resin through hole disposed in a central portion thereof and at least one resin fixing hole disposed in an outermost edge thereof, a semiconductor chip connected to first connection pads disposed on a first surface of the PCB by bumps, an upper encapsulant configured to hermetically seal the first surface of the PCB and the semiconductor chip, and a lower encapsulant protrusion configured to extend to a second surface of the PCB through the resin through hole and the resin fixing hole disposed in the first surface of the PCB.

### CROSS-REFERENCE TO RELATED APPLICATIONS

This application claims the benefit of Korean Patent Application No. 10-2010-0123730, filed on Dec. 6, 2010, in the Korean Intellectual Property Office, the disclosure of which is incorporated herein in its entirety by reference,

### BACKGROUND OF THE INVENTION

1. Field of the Invention

The inventive concept relates to a semiconductor package and a printed circuit board (PCB) serving as a basic frame of the semiconductor package, and more particularly, to a PCB including a resin through hole for a molded underfill (MUF) and a semiconductor package including the PCB.

2. Description of the Related Art

Semiconductor packages widely used for high-performance electronic devices have been variously developed more and more to downscale the semiconductor packages, expand the functionality of the semiconductor packages, and increase the internal capacities thereof. To reduce dimensions of a semiconductor package, a PCB is being adopted in place of a conventional lead frame. Also, bumps may be used instead of wires as connection terminals configured to connect a PCB or lead frame serving as a basic frame with a semiconductor chip. When the bumps are used as the connection terminals configured to connect the semiconductor chip and the basic frame, an MUF semiconductor package using only an encapsulant for a semiconductor package as an underfill resin may be introduced in a space between the semiconductor chip and the basic frame.

### SUMMARY OF THE INVENTION

The inventive concept provides a printed circuit board (PCB) for a semiconductor package that may improve the reliability of a semiconductor device by enhancing the adhesion of an encapsulant between a semiconductor chip and the PCB serving as a basic frame for a semiconductor package.

Additional features and utilities of the present general inventive concept will be set forth in part in the description which follows and, in part, will be obvious from the description, or may be learned by practice of the general inventive concept.

The inventive concept also provides a semiconductor package that may improve the reliability of a semiconductor device by enhancing the adhesion of an encapsulant between a semiconductor chip and the PCB serving as a basic frame for a semiconductor package.

The technical features and utilities of the inventive disclosure are not limited to the above disclosure; other features and utilities may become apparent to those of ordinary skill in the art based on the following descriptions.

Embodiments of the general inventive concept provide a PCB for a semiconductor package with improved solder joint reliability. The PCB includes a substrate of a semiconductor package including a metal interconnection disposed therein, the substrate having a first surface and a second surface disposed opposite the first surface, a first connection pad disposed on the first surface of the substrate and connected to a semiconductor chip, a second connection pad disposed on the second surface of the substrate and configured to outwardly expand functionality of the semiconductor chip, a resin through hole formed through the substrate in a central portion of the substrate, and at least one resin fixing hole formed through the substrate outside the central portion of the substrate.

The resin through hole may be formed in a region of the first surface of the substrate where a semiconductor chip is mounted. Alternatively, the resin through hole may be formed outside the region of the first surface of the substrate where the semiconductor chip is mounted.

The first connection pad may be connected to one of a wire and a bump. The second connection pad may be connected to a solder ball.

The substrate for the semiconductor package may be an embedded type substrate in which the semiconductor chip is inserted.

The PCB may further include an additional resin fixing hole disposed between the resin through hole and the resin fixing hole. The resin fixing hole may have a size equal to or greater than that of the resin through hole.

Embodiments of the general inventive concept also provide a semiconductor package with improved solder joint reliability. The semiconductor package includes a PCB for a semiconductor package including a resin through hole disposed in a central portion thereof and at least one resin fixing hole disposed in an outermost edge thereof, a semiconductor chip connected to a first connection pad disposed on a first surface of the PCB by a bump, an upper encapsulant configured to hermetically seal the first surface of the PCB and the semiconductor chip, and a lower encapsulant protrusion configured to extend to a second surface of the PCB through the resin through hole and the resin fixing hole disposed in the first surface of the PCB.

The semiconductor chip may be replaced by a stack structure of at least two semiconductor chips. In this case, the bump may be a through silicon via (TSV) configured to connect connection terminals of the at least two semiconductor chips with one another.

The lower encapsulant protrusion may have a straight-line shape and be connected to the at least one resin fixing hole across the resin through hole disposed in the central portion of the PCB, Alternatively, the lower encapsulant protrusion may have a cross shape such that the resin through hole of the PCB is disposed at an intersection of the lower encapsulant protrusion.

The PCB for the semiconductor package may further include an additional resin fixing hole disposed between the resin through hole and the resin fixing hole.

Embodiments of the general inventive concept also provide a semiconductor package with improved solder joint reliability. The semiconductor package includes a PCB for a semiconductor package including a resin through hole disposed in a central portion thereof and at least one resin fixing hole disposed in an outermost edge thereof, a semiconductor chip mounted on a first surface of the PCB, a wire configured to electrically connect a first connection pad disposed on the first surface of the PCB to the semiconductor chip, an upper encapsulant configured to hermetically seal the first surface of the PCB, the semiconductor chip, and the wire, and a lower encapsulant protrusion configured to extend to a second surface of the PCB through the resin through hole and the resin fixing hole disposed in the first surface of the PCB.

The resin through hole may be formed outside a region where the semiconductor chip is mounted. The lower encapsulant protrusion may have a smaller height than the solder ball.

Embodiments of the general inventive concept also provide a semiconductor package including: a printed circuit board (PCB) with first connection pads disposed on a first surface thereof and connected to a semiconductor chip, second connection pads disposed on a second surface thereof opposite the first surface and configured to outwardly expand functionality of the semiconductor chip, a resin through hole formed through the PCB in a central portion thereof, and at least one resin fixing hole formed therethrough outside the central portion thereof; an upper encapsulant disposed on the first surface of the PCB to hermetically seal the semiconductor chip and the first surface of the PCB: and a lower encapsulant protrusion extending through the resin through hole and the at least one resin fixing hole and along a portion of the second surface.

In an exemplary embodiment, the portion of the second surface in which the lower encapsulant extends is a first straight line extending from a first end of the PCB to a second end of the PCB opposite the first end, and the resin through hole and the at least one resin fixing hole are disposed along the same first straight line.

In an exemplary embodiment, the lower encapsulant further extends along a second straight line from a third end of the PCB to a fourth end of the PCB opposite the third end such that the first straight line and the second straight line form a cross shape, the resin through hole and the at least one resin fixing hole also being disposed along the same second straight line.

In an exemplary embodiment, the at least one resin fixing hole includes a plurality of resin fixing holes each disposed between the resin through hole and an outermost edge of the PCB.

In an exemplary embodiment, the lower encapsulant protrusion is formed to have an “I” shape such that perpendicular cross sections are provided at each end of the first straight line such that the resin through hole more effectively absorbs stress generated at a bonding surface between the PCB and the semiconductor chip.

In an embodiment, the second connection pads are formed of solder ball pads serving as conductive elements and the first connection pads are formed of bumps serving as conductive elements to which the semiconductor chip is connected.

Embodiments of the general inventive concept also provide a method of forming a semiconductor package, the method including: connecting a semiconductor chip on a printed circuit board (PCB) via first connection pads on a first surface of the PCB: disposing second connection pads on the PCB on a second surface thereof opposite the first surface; filling the space between the semiconductor chip and the PCB with a molded underfill resin such that the resin flows out to the second surface of the PCB through a resin through hole disposed at a center portion of the PCB and at least one resin fixing hole disposed outside the central portion of the PCB to form a lower encapsulant protrusion along the second surface of the PCB; and performing a molding process to hermetically seal the semiconductor chip and the first surface of the PCB.

In an exemplary embodiment, the lower encapsulant protrusion is formed within a recess region on the second surface where a lower mold of a molding apparatus is mounted.

### BRIEF DESCRIPTION OF THE DRAWINGS

These and/or other features and utilities of the present general inventive concept will become apparent and more readily appreciated from the following description of the embodiments, taken in conjunction with the accompanying drawings of which:

FIG. 1 is a perspective view of a semiconductor package according to an exemplary embodiment of the inventive concept;

FIG. 2 is a top view of a printed circuit board (PCB) applicable to the semiconductor package of FIG, 1;

FIG. 3 is a bottom view of the PCB of FIG. 2;

FIG. 4 is a bottom view of a modified example of the PCB of FIG. 2;

FIG. 5 is a bottom view of another modified example of the PCB of FIG. 2;

FIG. 6 is a bottom view of another modified example of the PCB of FIG. 2;

FIG. 7 is a bottom view of another modified example of the PCB of FIG. 2;

FIG. 8 is a perspective view of another modified example of the PCB of FIG. 2;

FIGS. 9A and 9B are sectional views of the PCB of FIG. 2 on which a semiconductor chip is mounted and a molding process is performed;

FIG. 9C is a bottom view of the PCB of FIG. 2 on which the semiconductor chip is mounted and the molding process is performed;

FIG. 10 is a cross-sectional view taken along a direction I-I′ of FIG. 9C;

FIG. 11 is a cross-sectional view taken along a direction II-II′ of FIG. 9C;

FIG. 12 is a cross-sectional view taken along a direction III-III′ of FIG. 9C;

FIG. 13 is a sectional view of a semiconductor package that corresponds to a modified example of FIG, 12, according to another exemplary embodiment of the inventive concept;

FIGS. 14A through 14C are sectional views of the PCB of FIG. 8 on which a semiconductor chip is mounted and a molding process is performed;

FIG. 14D is a bottom view of a semiconductor package that includes the PCB of FIG. 8 on which a semiconductor chip is mounted and a molding process is performed, according to still another exemplary embodiment of the inventive concept;

FIG. 15 is a cross-sectional view taken along a direction I-I′ of FIG. 14D;

FIG. 16 is a cross-sectional view taken along a direction II-II′ of FIG. 14D;

FIG. 17 is a bottom view of a semiconductor package that corresponds to a modified example of FIG. 9C, according to yet another exemplary embodiment of the inventive concept;

FIG. 18 is a bottom view of a semiconductor package that corresponds to another modified example of FIG. 9C, according to yet another exemplary embodiment of the inventive concept;

FIG. 19 is a top view of a PCB that corresponds to a modified example of FIG. 2, according to yet another exemplary embodiment of the inventive concept;

FIGS. 20A and 20B are sectional views taken along a direction I-I′ and II-II′ of FIG. 19, illustrating the PCB of FIG. 19 on which a semiconductor chip is mounted and a molding process is performed;

FIG. 20C is a bottom view of a semiconductor package according to still another exemplary embodiment of the inventive concept;

FIG, 21 is a cross-sectional view taken along a direction I-I′ of FIG. 20C;

FIG. 22 is a cross-sectional view taken along a direction II-II′ of FIG. 20C;

FIG. 23 is a cross-sectional view taken along a direction III-III′ of FIG. 20C;

FIGS. 24 through 26 are a top view and system block diagrams of electronic devices according to embodiments of the inventive concept; and

FIG. 27 is a perspective view of an electronic device according to an embodiment of the inventive concept.

### DETAILED DESCRIPTION OF THE PREFERRED EMBODIMENTS

The inventive concept will now be described more fully hereinafter with reference to the accompanying drawings, in which embodiments of the inventive concept are shown. This inventive concept may, however, be embodied in different forms and should not be construed as limited to the embodiments set forth herein. Rather, these embodiments are provided so that this disclosure is thorough and complete and fully conveys the scope of the inventive concept to one skilled in the art. In the drawings, the thicknesses of layers and regions are exaggerated for clarity, and proportions of components may be exaggerated or reduced. Like numbers refer to like elements throughout.

It will be understood that when an element or layer is referred to as being “on”, “connected to”, or “coupled to” another element or layer, it can be directly on, connected, or coupled to the other element or layer or intervening elements or layers may be present. In contrast, when an element is referred to as being “directly on”, “directly connected to”, or “directly coupled to” another element or layer, there are no intervening elements or layers present. Meanwhile, spatially relative terms, such as “between” and “directly between” or “adjacent to” and “directly adjacent to” and the like, which are used herein for ease of description to describe one element or feature's relationship to another elements or features as illustrated in the figures, should be interpreted similarly.

It will be understood that, although the terms first, second, etc. may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of the present inventive concept.

As used herein, the singular forms “a”, “an”, and “the” are intended to include the plural forms as well, unless the context clearly indicates otherwise. It will be further understood that the terms “comprises” and/or “comprising”, when used in this specification, specify the presence of stated features, integers, steps, operations, elements, components, and/or groups thereof, but do not preclude the presence or addition of one or more other features, integers, steps, operations, elements, components, and/or groups thereof.

Unless otherwise defined, all terms including technical and scientific terms used herein have the same meaning as commonly understood by one of ordinary skill in the art to which this inventive concept belongs.

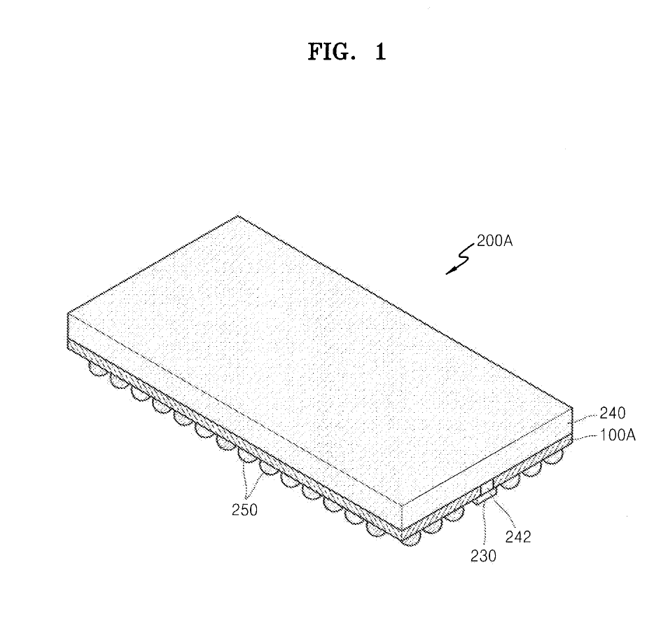

FIG. 1 is a perspective view of a semiconductor package 200A according to an exemplary embodiment of the inventive concept.

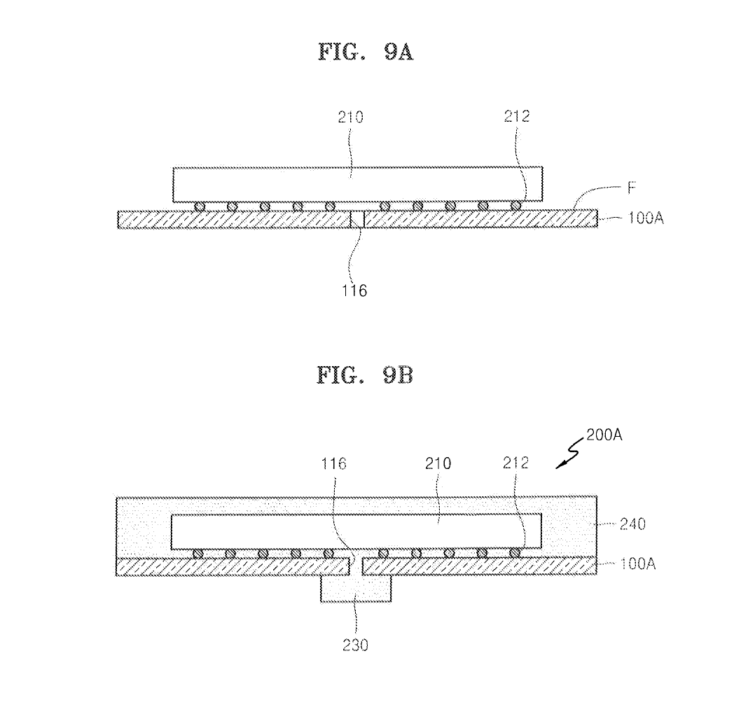

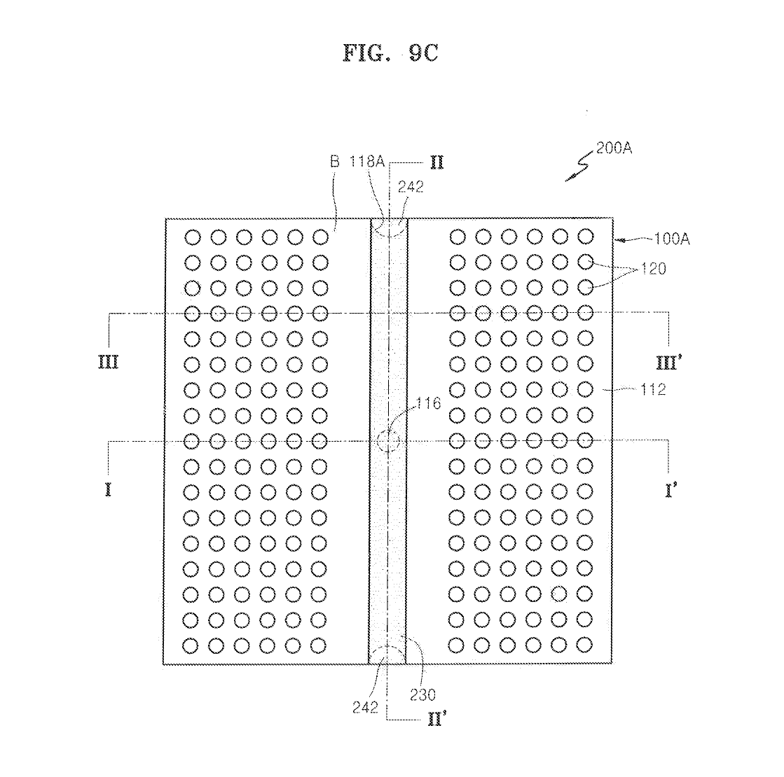

Referring to FIG. 1, the semiconductor package 200A according to the present embodiment may include a printed circuit board (PCB) 100A having a through hole region, a semiconductor chip (refer to 210 of FIG. 9B) mounted on the PCB 100A, an upper encapsulant 240 disposed on the PCB 100A, and a lower encapsulant protrusion 230 disposed under the PCB 100A to fill the through hole region of the PCB 100A.

The PCB 100A serving as a basic frame may be a PCB for a semiconductor package, and the PCB 100A may include a resin through hole formed in a central portion thereof and at least one resin fixing hole formed outside the resin through hole. Structures and modified examples of the PCB 100A will be described in detail later with reference to the accompanying drawings.

The semiconductor package 200A may include the semiconductor chip, which may be connected to first connection pads (not shown) disposed on a first surface for example, a top surface of the PCB 100A by bumps. The semiconductor chip may be a multifunctional semiconductor chip, such as a memory device, a logic device, a microprocessor, an analog device, a digital signal processor, or a system on chip. In addition, the semiconductor chip may be a multi-chip having at least two stacked semiconductor chips. For instance, the at least two semiconductor chips may be identical memory devices or include at least one memory device and at least one micro-controller device.

The semiconductor package 200A may include the upper encapsulant 240 and the lower encapsulant protrusion 230. The upper encapsulant 240 may hermetically seal the top surface of the PCB 100A and the semiconductor chip. The lower encapsulant protrusion 230 may extend from a second surface for example, a bottom surface of the PCB 100A through the resin through hole and the at least one resin fixing hole of the PCB 100A. The upper encapsulant 240 and the lower encapsulant protrusion 230 may be formed of an epoxy mold compound (EMC). Each of the upper encapsulant 240 and the lower encapsulant protrusion 230 may be a molded-underfill (MUF)-type encapsulant configured not only to fill a space between the semiconductor chip and the PCB 100A, but also to hermetically seal the semiconductor package 200A. By using the MUF-type encapsulant, a molding process may be performed without an additional underfill process. Furthermore, the molding process may be simplified by using an EMC with verified reliability as the MUF-type encapsulant, and thus the entire fabricating process may be simplified.

According to an embodiment of the inventive concept, the resin through hole may have a semicircular, rectangular, or semielliptical shape. However, the resin through hole may have any of various other shapes.

In this case, a resin portion and a resin fixing portion 242 may function to significantly improve the reliability of the semiconductor package 200A. Specifically, the resin portion may clip upper and lower portions of the PCB 100A together through the resin through hole. The resin fixing portion 242 may clip the upper and lower portions of the PCB 100A together through the at least one resin fixing hole at an edge of the PCB 100A.

More specifically, there may be a difference in coefficient of thermal expansion (CTE) between the semiconductor chip and the PCB 100A of the semiconductor package 200A. Thus, when stress concentrates on a bonding surface between the PCB 100A and the semiconductor chip during a reliability test, such as a temperature cycle test, the stress may be locked into and relieved by the encapsulant filling the resin through hole and the at least one resin fixing hole. Meanwhile, the temperature cycle test may involve repeatedly subjecting a semiconductor package to extreme changes in temperature between −55° C. and 125° C. for a predetermined amount of time to examine the electrical performance and external defects of the semiconductor package.

In addition, the semiconductor package 200A may further include solder balls 250 serving as conductive elements bonded to second connection pads disposed on the second surface of the PCB 100A. When the semiconductor package 200A is a pin-grid-array (PGA) type, the conductive elements bonded to the second connection pads may be pins instead of the solder balls.

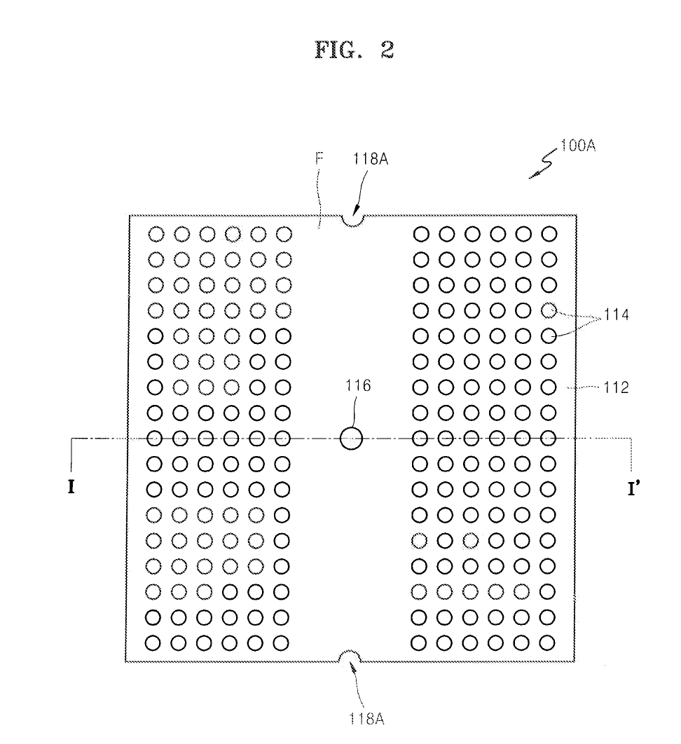

FIG. 2 is a top view of a PCB applicable to the semiconductor package 200A of FIG. 1, and FIG, 3 is a bottom view of the PCB shown in FIG. 2.

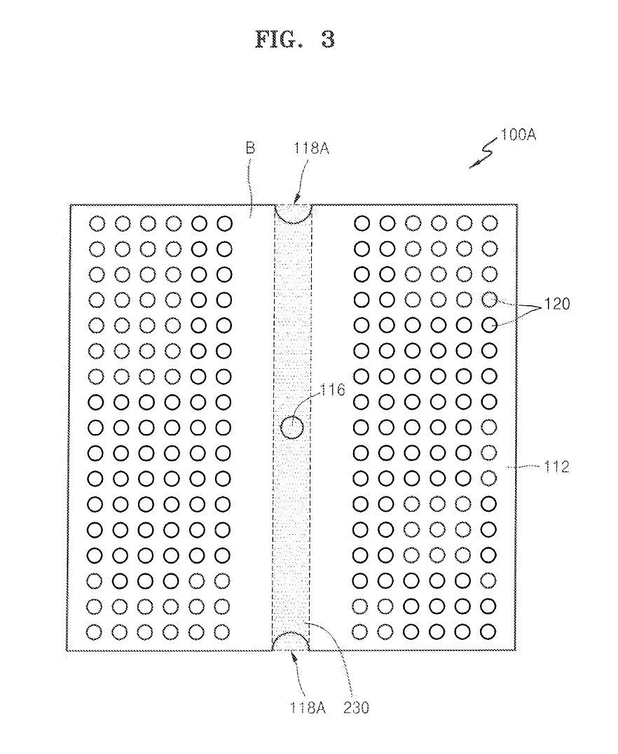

Referring to FIGS. 2 and 3, the PCB 100A, as the PCB applicable to the semiconductor package 200A, may include (1) a substrate 112 for a semiconductor package including metal interconnections therein and having first and second surfaces F and B disposed opposite each other, (2) first connection pads 114 disposed on the first surface (e.g., a top surface) F of the substrate 112 and connected to the semiconductor chip, (3) second connection pads 120 disposed on the second surface B of the substrate 112 and configured to outwardly expand the functionality of the semiconductor chip, (4) a resin through hole 116 formed in a central portion of the substrate 112 through the first surface F and the second surface B of the substrate 112, and (5) at least one resin fixing hole 118A formed outside the central portion of the substrate 112 through the first surface F and the second surface B of the substrate 112.

The substrate 112 may be formed of a resin, a photosensitive liquid dielectric material, a photosensitive dry-film dielectric material, a flexible and thermosetting polyimide dry-film, a thermosetting liquid dielectric material, resin-coated copper (RCC) foil, a thermoplastic material, or a flexible resin. In addition, the substrate 112 may be formed of a ceramic material. However, the above-described materials for forming the substrate 112 are only examples, and embodiments of the inventive concept are not limited thereto.

Although not shown, the metal interconnections of the substrate 112 may be electrically connected to each other by a via contact structure configured to connect the first and second connection pads 114 and 120. Furthermore, at least one internal interconnection layer may be formed in the substrate 112. Specifically, the metal interconnections of the substrate 112 and the first and second connection pads 114 and 120 formed on the first and second surfaces F and B of the substrate 112, may be, for example, formed of aluminum(Al) or copper (Cu) foil. In some embodiments, surfaces of the metal interconnections may be plated with tin (Sn), gold (Au), nickel (Ni), or lead (Pb).

Although not shown, the PCB 100A may further include a protection layer (not shown) configured to expose only the first and second connection pads 114 and 120 and to cover remaining regions of the PCB 100A, In this case, the protection layer may be formed of a photo solder resist, and the protection layer may be patterned using a lithography process. The protection layer may be formed as a solder mask define (SMD) type configured to partially expose the first and second connection pads 114 and 120 or as a non solder mask define (NSMD) type configured to wholly expose the first and second connection pads 114 and 120.

In the present specification, the central portion where the resin through hole 116 is formed refers to a region of the substrate 112 disposed between the resin fixing holes 118A.

Also, the first connection pads 114 may be bump pads to which bumps formed on bonding pads of the semiconductor chip may be connected. The second connection pads 120 disposed on the second surface B of the substrate 112 may be solder ball pads to which solder balls may be connected.

The resin through hole 116 and the resin fixing holes 118A may form a flow path through which the encapsulant e.g., an EMC resin configured to hermetically seal an upper portion of the substrate 112 flows to a lower portion of the substrate 112. Thus, according to the inventive concept, a portion of the encapsulant may flow from the first surface F of the substrate 112 through the resin through hole 116 and the resin fixing holes 118A to the second surface e.g., a bottom surface B of the substrate 112 and form the lower resin protrusion 230 as illustrated with dotted lines in FIG. 3. To this end, a recess region where the lower encapsulant protrusion 230 may be formed may be formed in a lower mold mounted on a molding apparatus.

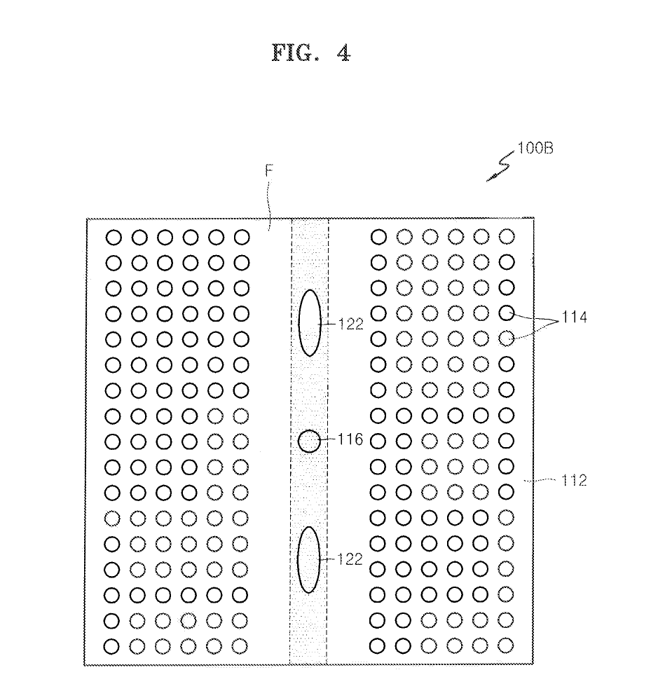

FIGS. 4 through 7 are bottom views of modified examples of the PCB shown in FIG. 2.

FIG. 4 shows a PCB 100B for a semiconductor package as a modified example of the PCB of FIG. 2, in which an additional resin fixing hole 122 may be disposed between the resin through hole 116 and an outermost edge of the substrate 112, instead of the resin fixing holes 118A disposed on the outermost edge of the substrate 112 as shown in FIG. 2. Thus, the PCB 100B may be fixed by two clipping regions, that is, the resin through hole 116 and the additional resin fixing hole 122. As a result, the encapsulant filling the resin through hole 116 and the additional resin fixing hole 122 may more effectively absorb stress generated at a bonding surface between the PCB 100B and the semiconductor chip.

The additional resin fixing hole 122 may have any of various other shapes, such as a circular shape, a lozenge shape, or a rectangular shape, instead of an elliptical shape shown in FIG. 4. Also, the first connection pads for instance, the bump pads 114 formed on the first surface F of the substrate 112 may be variously arranged as needed.

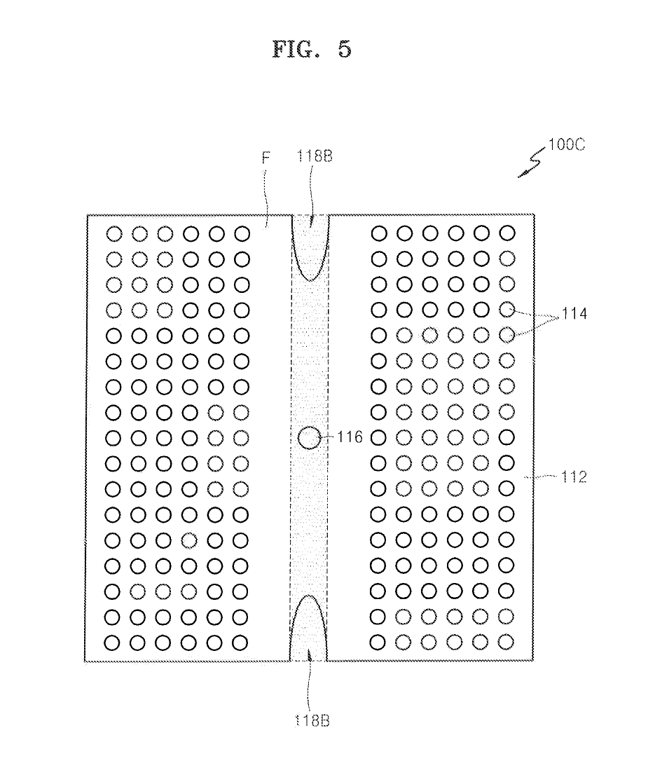

FIG. 5 shows a PCB 100C for a semiconductor package as another modified example of the PCB of FIG. 2, in which a resin fixing hole 118B has an elongated slit shape instead of a semicircular shape shown in FIG. 2 and the resin fixing hole 118B is formed to a greater width than the resin through hole 116 as illustrated with dotted lines in FIG. 5. Accordingly, a contact area between the encapsulant e.g., an EMC resin configured to fix the substrate 112 via the resin fixing hole 118B may be designed to be as great as possible. Accordingly, the encapsulant configured to fill the resin fixing hole 118B may more effectively absorb stress generated at a bonding surface between the PCB 100C and the semiconductor chip. Meanwhile, in the PCB 100C according to an embodiment of the inventive concept, the resin fixing hole 118B may be formed to a width equal to or greater than that of the resin through hole 116.

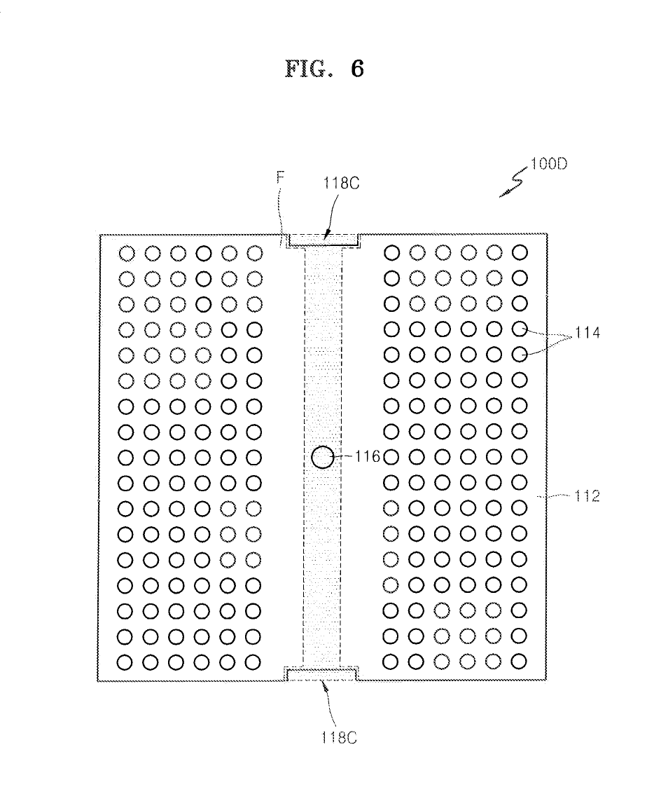

FIG. 6 shows a PCB 100D for a semiconductor package as another modified example of the PCB of FIG. 2, in which a resin fixing hole 118C has a rectangular shape instead of the semicircular shape shown in FIG. 2. Accordingly, similar to the PCB 100C of FIG. 5, a contact area between the encapsulant e.g., an EMC resin configured to fix the substrate 112 via the resin fixing hole 118C may be designed to be as great as possible. Thus, a lower encapsulant protrusion formed on a second surface e.g., a bottom surface of the PCB 100D may be formed to have an “I” shape as illustrated with dotted lines in FIG. 6. As a result, the encapsulant the resin through hole 116 may more effectively absorb stress generated at a bonding surface between the PCB 100D and the semiconductor chip.

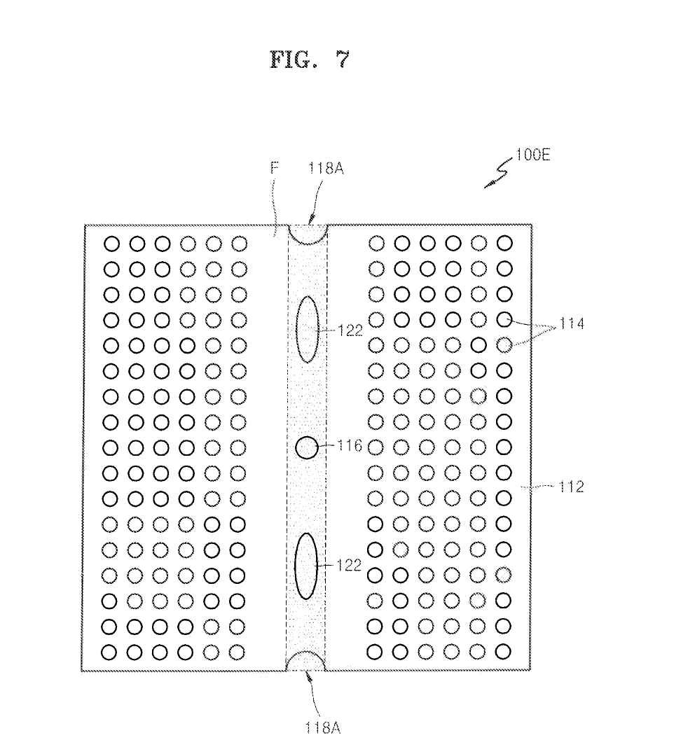

FIG. 7 shows a PCB 100E for a semiconductor packages as another modified example of the PCB of FIG. 2, in which, besides the resin fixing holes 118A, an additional resin fixing hole 122 is formed between the resin through hole 116 and the resin fixing holes 118A. Accordingly, the PCB 100E may be fixed by three clipping regions, that is, the resin through hole 116, the additional resin fixing hole 122, and the resin fixing holes 118A. In FIG. 7, a dotted portion refers to a lower encapsulant protrusion disposed under a bottom surface of the PCB 100E. Thus, a contact area between the encapsulant e.g., an EMC resin configured to fix the substrate 112 via the resin through hole 116, the additional resin fixing hole 122, and the resin fixing holes 118A may be designed to be as great as possible. As a result, the encapsulant filling the resin through hole 116, the additional resin fixing hole 122, and the resin fixing holes 118A may more effectively absorb stress generated at a bonding surface between the PCB 100E and the semiconductor chip.

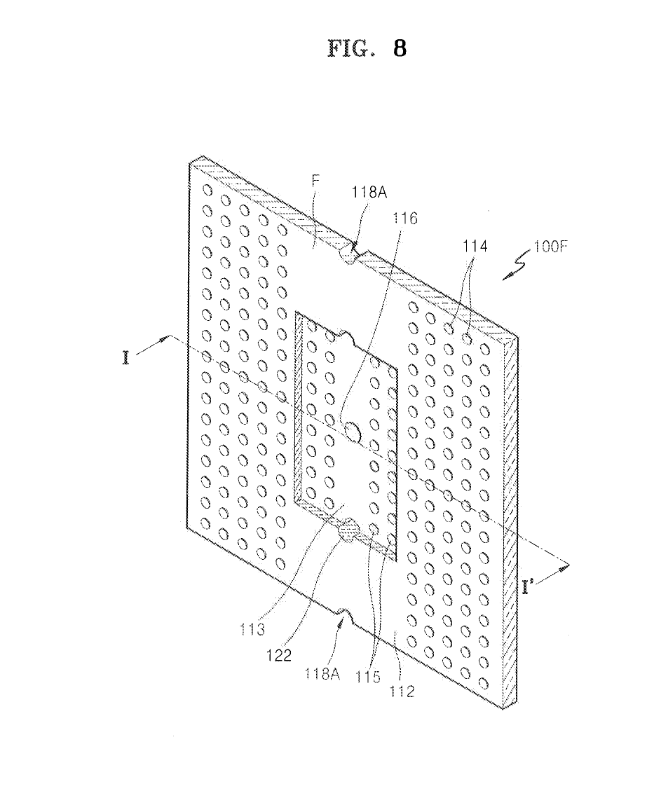

FIG. 8 is a perspective view of a PCB 100F for semiconductor package as another modified example of the PCB of FIG. 2.

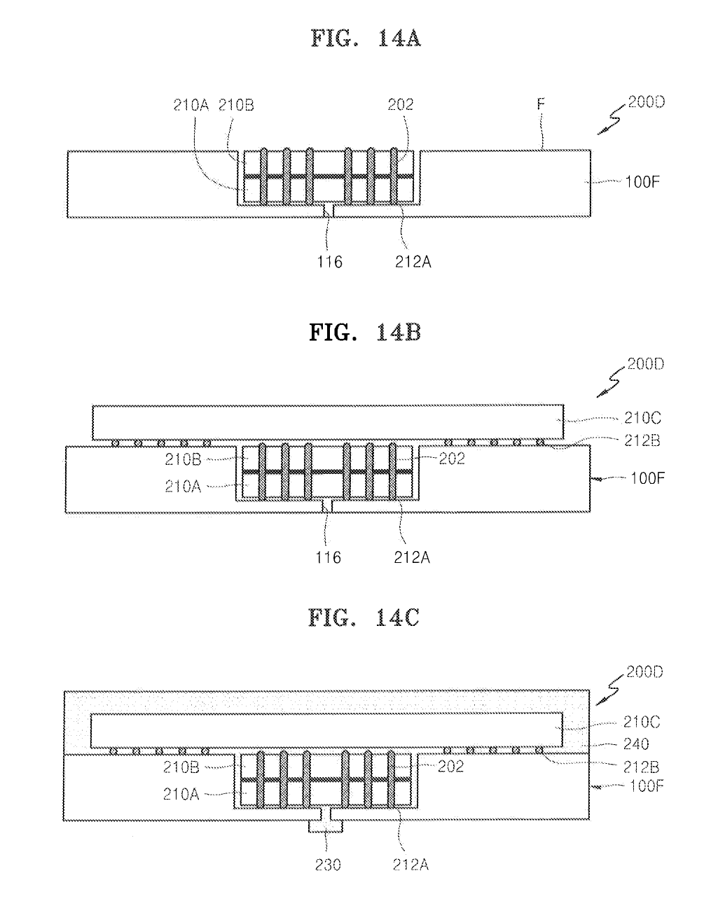

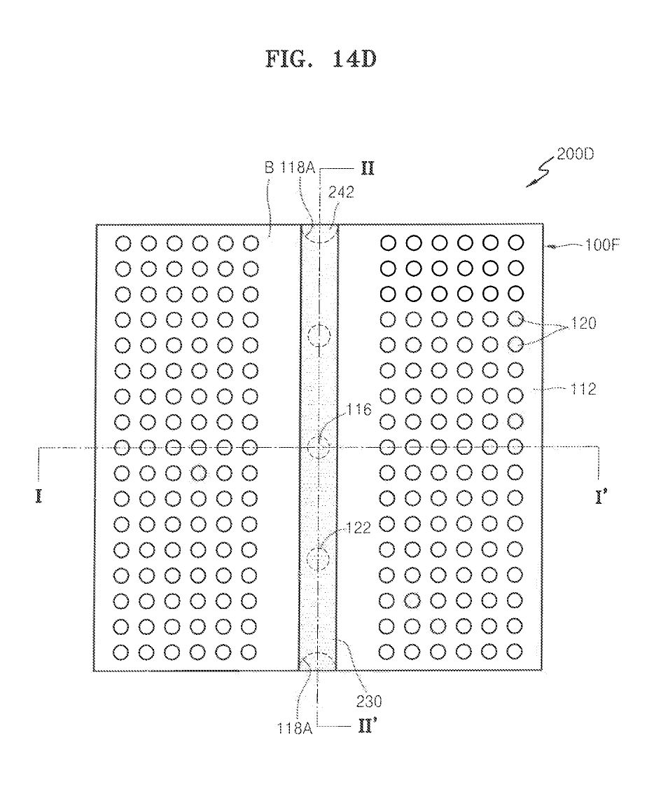

Referring to FIG. 8, the PCB 100F according to an embodiment of the inventive concept may be an embedded-type PCB in which a semiconductor chip is mounted on a recessed surface 113 of the substrate 112. A first semiconductor chip may be electrically connected to bump pads 115 provided on the recessed surface 113 of the substrate 112, while a second semiconductor chip may be mounted on and electrically connected to the first connection pads 114 disposed on the substrate 112. Here, the additional resin fixing hole 122 for the first semiconductor chip may be formed at an edge of the recessed surface 113, and the resin fixing holes 118A for the second semiconductor chip may be formed at the outermost edge of the substrate 112. Thus, stress generated at a bonding surface between the two semiconductor chips and the PCB 100F may be absorbed by the additional resin fixing hole 122 and the resin fixing holes 118A. A detailed structure of the PCB 100F will be described in detail later with reference to FIGS. 14 through 16.

Meanwhile, in the above-described PCBs 100A, 100B, 100C, 100D, 100E and 100F for semiconductor packages according to various embodiments, the resin fixing holes 118a may be formed to a width greater than or equal to that of the resin through hole 116.

FIGS. 9A and 9B are sectional views of the PCB of FIG. 2 on which a semiconductor chip 210 is mounted and a molding process is performed.

Referring to FIGS. 9A and 9B, the semiconductor chip 210 may be mounted on the top surface of the above-described PCB 100A by bumps 212. The bumps 212 may be formed on an under bump metallurgy (UBM) layer previously provided on the bonding pads of the semiconductor chip. The bumps 212 may be connected on a one-to-one basis to the bump pads (refer to 114 of FIG. 2) provided on the PCB 100A, The mounting of the semiconductor chip 210 on the PCB 100A may be performed using a high-temperature thermal process, such as a wave soldering process or a reflow soldering process.

Subsequently, the molding process may be performed on the PCB 100A on which the semiconductor chip 210 is mounted. An encapsulant for a semiconductor package used in the molding process may be an MUF encapsulant that may prevent occurrence of void defects at a bonding surface between the semiconductor chip 210 and the PCB 100A. In addition, the MUF encapsulant may include a material that has a relatively low ion content and a relatively low hygroscopic property and is highly adhesive to both the semiconductor chip 210 and the PCB 100A and highly flowable.

Due to the molding process, the upper encapsulant 240 may be formed on the top surface of the PCB 100A and hermetically seal each of the semiconductor chip 210 and the top surface of the PCB 100A. In addition, the encapsulant may flow out to the bottom surface of the PCB 100A through the resin through hole (refer to 116 of FIG. 2) and the resin fixing hole (refer to 118A of FIG. 2) formed in the PCB 100A so that the lower encapsulant protrusion 230 can be on the bottom surface of the PCB 100A.

The lower encapsulant protrusion 230 may be formed by filling a mold with the encapsulant in a vacuum using molding equipment. That is, to form the lower encapsulant protrusion 230, the encapsulant may fill a space between the PCB 100A and the semiconductor chip 210 disposed thereon and flow out to the bottom surface of the PCB 100A through the resin through hole 116 and the resin fixing holes 118A. Accordingly, the space between the semiconductor chip 210 and the PCB 100A may be filled without requiring an additional underfill resin. Also, since the flow of the encapsulant may be controlled through the resin through hole 116 and the resin fixing holes 118A, the occurrence of void defects between the semiconductor chip 210 and the PCB 100A may be reduced or prevented.

FIG. 9C is a bottom view of the PCB of FIG. 2 on which the semiconductor chip is mounted and the molding process is performed.

Referring to FIG. 9C, in the semiconductor package 200A according to an embodiment of the inventive concept, the second connection pads 120 e.g., solder ball pads may be arranged in a matrix shape on the bottom surface of the PCB 100A. Conductive elements e.g., solder balls may be adhered to the second connection pads 120 to outwardly expand the functionality of the semiconductor package 200A. When the conductive elements configured to outwardly expand the functionality of the semiconductor package 200A are pins, the pins may be adhered to the second connection pads 120 instead of the solder balls.

The lower encapsulant protrusion 230 may be formed as a straight-line type on the bottom surface of the PCB 100A. The resin fixing portion 242 filling the resin fixing holes 118A may surround the PCB 100A as a clip type. The encapsulant filling the resin fixing portion 242 and the resin through hole 16 may function to fix and lock the PCB 100A in a transverse direction when the PCB 100A and the semiconductor chip 210 are thermal stressed and repetitively contracted and expanded. Accordingly, thermal stress generated in the semiconductor package 200A may be absorbed by the lower encapsulant protrusion 230 and the upper encapsulant (refer to 240 of FIG. 9B).

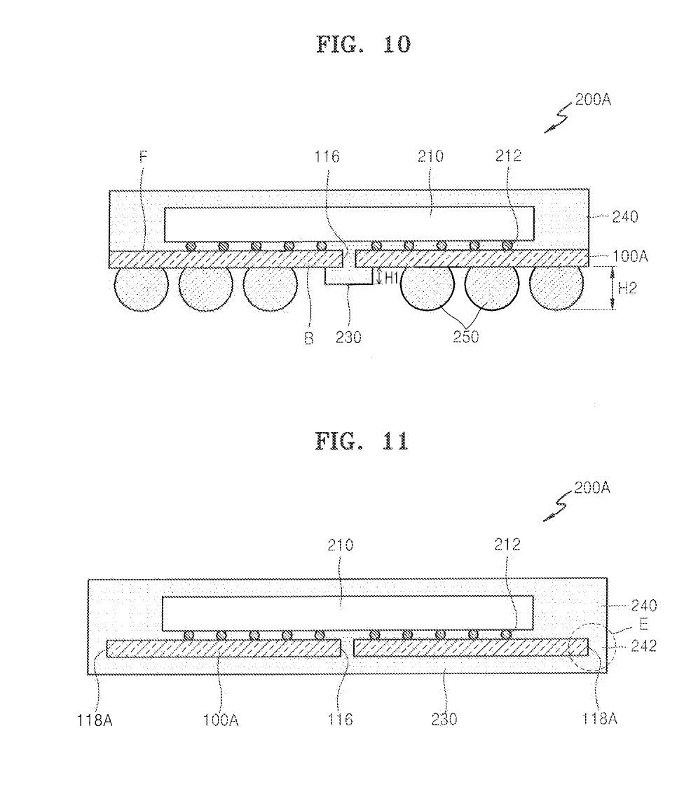

FIG. 10 is a cross-sectional view taken along a direction I-I′ of FIG. 9C, FIG. 11 is a cross-sectional view taken along a direction II-II′ of FIG. 9C, and FIG. 12 is a cross-sectional view taken along a direction III-III′ of FIG. 9C.

Referring to FIGS. 10 through 12, the solder balls 250 may be adhered to the second connection pads 120 provided on the bottom surface of the PCB 100A of FIG. 9C. The solder balls 250 may be adhered to the second connection pads 120 using a reflow soldering process.

Here, the reflow soldering process may refer to a soldering process performed while melting a previously prepared solder paste or solder cream. Specifically, the reflow soldering process may include melting a solder material (e.g., tin(Sn)/lead(Pb) or Sn/Pb/gold(Au)) having a lower melting point than a base material of a joint portion. Thus, a melted material may flow and wet a surface of the joint portion, and simultaneously, metal elements forming the solder material may diffuse between elements of the base metal of the joint portion to form an alloy layer in which the metal elements of the solder material and the elements of the base metal are strongly combined.

For example, the reflow soldering process may have a heat-up period, a soaking period, a reflow soldering period, and a cooling period having different process temperatures. The heat-up period may range from room temperature, about 25° C., to a temperature of about 100° C., the soaking period may range from a temperature of about 100° C. to a temperature of about 200° C., the reflow soldering period may range from a temperature of about 200° C. to a peak temperature of about 245° C., and the cooling period may range from a temperature of about 200° C. to room temperature. Here, the temperature range of the reflow soldering period may be near a melting point of the solder material. The melting point of the solder material may depend on elements of the solder material. For instance, a solder material formed of 96.5 Sn/3.5 Ag may have a melting point of about 221° C., and a solder material formed of 99.3 Sn/0.7 Cu may have a melting point of about 227° C., Thus, the reflow soldering period may vary according to the composition of the solder material, In addition, the temperature ranges provided for the description of the reflow soldering process are only examples, and the inventive concept is not limited thereto.

Meanwhile, a height H1 of the lower encapsulant protrusion 230 may be less than a height H2 of the solder balls 250. Otherwise, the formation of the solder balls 250 may be hampered by the lower encapsulant protrusion 230 when the semiconductor package 200A is mounted on a mother board of an electronic device.

Referring to the cross-sectional view of FIG. 10 taken along the direction I-I′ of FIG. 9C, the lower encapsulant protrusion 230 formed through the resin through hole 116 may bisect the PCB 100A in a lateral direction. Accordingly, when stress is generated in the semiconductor package 200A, the lower encapsulant protrusion 230 configured to bisect the PCB 100A through the resin through hole 116 may absorb the stress from the central portion of the PCB 100A. The stress may be generated by expanding and contracting the bonding surface between the semiconductor chip 210 and the PCB 100A due to an external temperature variation.

Referring to the cross-sectional view of FIG. 11 taken along the direction II-II′ of FIG, 9C, the lower encapsulant protrusion 230 may absorb the stress from both the central portion where the resin through hole 116 is formed and an edge portion E where the resin fixing holes 118A is formed, Accordingly, stress applied to the bonding surface between the semiconductor chip 210 and the PCB 100a, for example, stress applied to the bumps 212 formed on the semiconductor chip 210, may be reduced. As a result, formation of fine cracks in the bumps 212 during a temperature cycle test may be inhibited.

Although the PCB 100A of FIG. 2 is described in the present embodiment, when the PCB 100A is replaced by any of the PCBs 1006 to 100E shown in FIGS. 4 through 7, the above-described additional effects may be obtained.

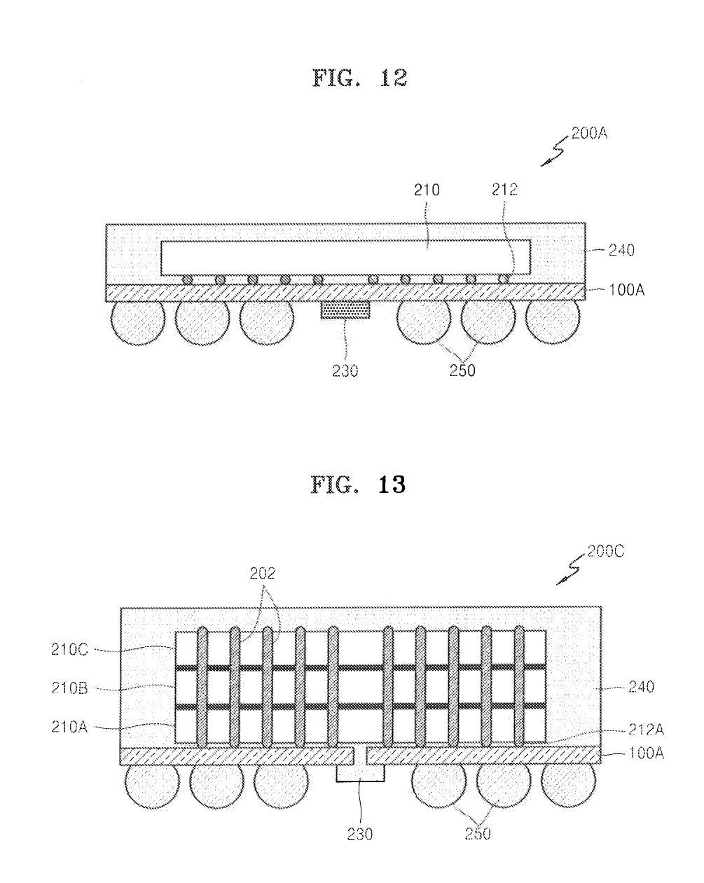

FIG. 13 is a sectional view of a semiconductor package that corresponds to a modified example of FIG. 12, according to another embodiment of the inventive concept.

The previous embodiment describes that the semiconductor package 200A includes only one semiconductor chip 210. However, referring to FIG. 13, a multi-chip package (MCP) 200C may include a stack structure of a plurality of semiconductor chips 210A, 210B, and 210C instead of the semiconductor chip 210. In this case, through-silicon vies (TSVs) 202 formed through bonding pads formed on the semiconductor chips 210A, 210B, and 210C may be formed on the semiconductor chips 210A, 210B, and 210C. Accordingly, in the multi-chip package (MCP) 200C to which a TSV technique is applied, the resin through hole 116, the resin fixing holes 118A, and the lower encapsulant protrusion 230 according to the inventive concept may reduce stress generated at bonding surfaces between the semiconductor chips 210A, 210B, and 210C and the PCB 100a, thereby improving the reliability of the MCP 200C.

FIGS. 14A to 14C are sectional views of the PCB 100F of FIG. 8 on which a plurality of semiconductor chips are mounted and a molding process is performed.

FIG. 14A is a cross-sectional view taken along a direction I-I′ of FIG. 8, illustrating the PCB 100F on which the plurality of semiconductor chips are mounted and the molding process is performed. Initially, the semiconductor chips 210A and 210B may be stacked as first semiconductor chips. Specifically, the semiconductor chips 210A and 210B having the TSVs 202 may be inserted and mounted in the recessed surface (refer to 113 in FIG. 8) of the PCB 100F. In this case, lower ends 212A of the TSVs 202 may be connected to the bump pads 115 prepared in the recessed surface 113 of the PCB 100F (refer to FIG. 8). Meanwhile, the first semiconductor chips 210A and 210B may form a single semiconductor chip as in the previous embodiment.

Thereafter, the semiconductor chip 210C may be mounted as a second semiconductor chip on the PCB 100F on which the first semiconductor chips 210A and 210B are mounted. In this case, bumps 212B formed on the second semiconductor chip 210C may be connected to the first connection pads 114 (e.g., the bump pads 115 of FIG. 8) formed on the PCB 100F. In this case, top ends of the TSVs 202 of the first semiconductor chips 210A and 210B may not be electrically connected to the second semiconductor chip 210C.

Subsequently, the molding process may be performed on the PCB 100F on which the second semiconductor chip 210c is mounted. the upper encapsulant 240 may be formed on the top surface of the PCB 100F to hermetically seal the semiconductor chips 210A, 210B, and 210C. Simultaneously, the lower encapsulant protrusion 230 having a straight line shape may be formed on the bottom surface of the PCB 100F. Although partially not shown, the lower encapsulant protrusion 230 may be formed as shown in FIG. 14D on the bottom surface of the PCB 100F through the resin through hole 116, the additional resin fixing hole 122, and the resin fixing holes 118A prepared in the PCB 100F.

FIG. 14D is a bottom view of a semiconductor package 200D including the PCB 100F of FIG. 8 on which a semiconductor chip is mounted and a molding process is performed, according to a third embodiment of the inventive concept.

Referring to FIG. 14D, the semiconductor package 200D according to the present embodiment may include the lower encapsulant protrusion 230 formed in the bottom surface of the PCB 100F. The second connection pads (e.g., solder ball pads) 120 may be formed on the bottom surface of the PCB 100F on opposite sides of the lower encapsulant protrusion 230. In this case, the lower encapsulant protrusion 230 may generally have a line shape to fill the resin through hole 116, the additional resin fixing hole 122, and the resin fixing holes 118A. Here, the resin fixing portion 242 may refer to an encapsulant configured to fill the resin through holes 118A.

The inventive concept may be characterized by the lower encapsulant protrusion 230 provided on the bottom surface of the PCB 100F to fill the resin through hole 116, the additional resin fixing hole 122, and the resin fixing holes 118A without forming an additional underfill resin on the top surface of the PCB 100F.

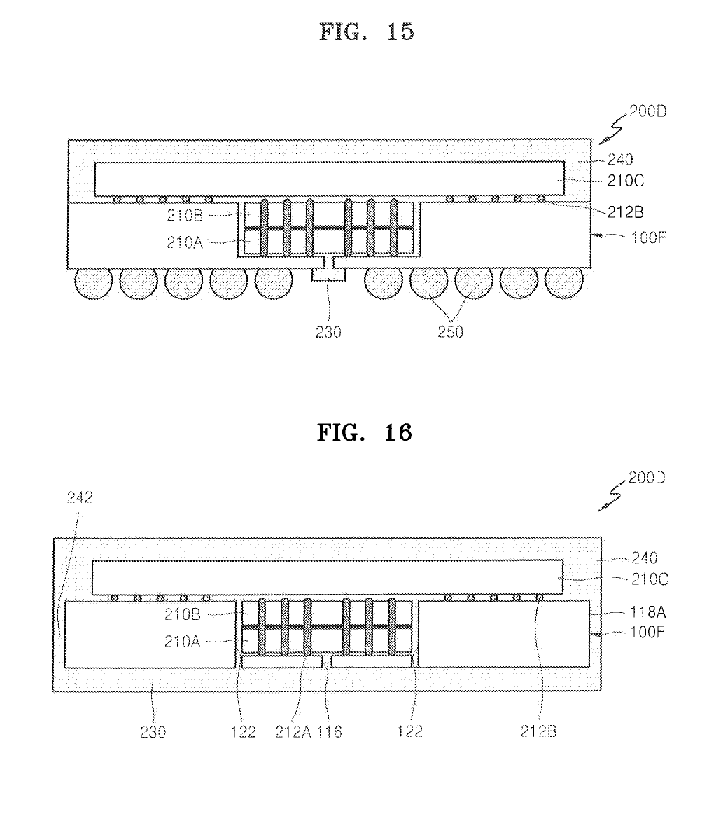

FIG. 15 is a cross-sectional view taken along a direction I-I′ of FIG. 14D, and FIG. 16 is a cross-sectional view taken along a direction II-II′ of FIG. 14D.

Referring to FIGS. 15 and 16, conductive elements (e.g., solder balls) 250 may be adhered to the second connection pads 120 prepared on the bottom surface of the PCB 100F of FIG. 14C. Here, the lower encapsulant protrusion 230 may have a smaller height than the solder balls 250. Otherwise, the formation of the solder balls 250 may be hampered by the lower encapsulant protrusion 230 when the semiconductor package 200D is mounted on a mother board of an electronic device.

In FIG. 15, the lower encapsulant protrusion 230 formed through the resin through hole 116 may bisect the PCB 100F. Accordingly, when stress is generated at the bonding surfaces between the semiconductor chips 210A, 210B, and 210C and the PCB 100F, the lower encapsulant protrusion 230 configured to bisect the PCB 100F through the resin through hole 116 may function to absorb the stress from a central portion of the PCB 100F.

In FIG. 16, the lower encapsulant protrusion 230 may absorb stress generated at the bonding surfaces between the semiconductor chips 210A, 210B, and 210C and the PCB 100F. Specifically, the lower encapsulant protrusion 230 may simultaneously absorb stress from the central portion where the resin through hole 116 is formed, a middle portion where the additional resin fixing hole 122 is formed, and an edge portion where the resin fixing holes 118A are formed.

In particular, the encapsulant filling the additional resin fixing hole 122 may be configured to absorb stress generated in a region where first semiconductor chips 210A and 210B are mounted, while the resin fixing portion 242 filling the resin fixing hole 118A may be configured to effectively absorb stress generated in a region where the second semiconductor chip 210C is mounted. Accordingly, stress applied to the lower ends 212A and the bumps 212B prepared at the bonding surfaces between the semiconductor chips 210A, 210B, and 210C and the PCB 100F may be reduced. As a result, generation of fine cracks in the lower ends 212A and bumps 212B in a temperature cycle test may be reduced or prevented.

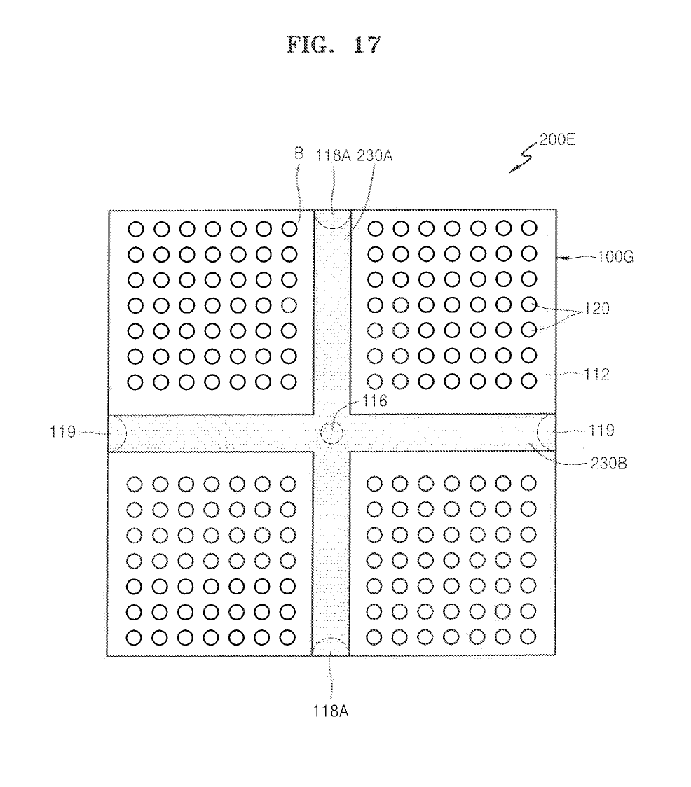

FIG. 17 is a bottom view of a semiconductor package that corresponds to a modified example of FIG. 9C, according to another embodiment of the inventive concept.

FIG. 9C shows that the lower encapsulant protrusion 230 has a straight-line shape to connect the resin through hole 116 and the resin fixing holes 118A. However, referring to FIG. 17, the lower encapsulant protrusion 230A and a lower encapsulant protrusion 230B may have a cross shape on a PCB 100G and at least one additional resin fixing hole 119 may be further prepared at an edge of a horizontal axis of the PCB 100E to connect the resin fixing holes 118A and the additional resin fixing holes 119 with the resin through hole 116 disposed in a center of the lower encapsulant protrusion 230. Thus, the second connections pads (e.g., solder ball pads) 120 formed on the PCB 100G may be equally divided into four groups based on the lower encapsulant protrusions 230A and 230B.

In addition, the lower encapsulant protrusions 230A and 230B may be formed on a second surface of the PCB 100G to intersect each other as shown in FIG. 17. In this case, an additional resin fixing hole may be formed between the resin through hole 116 and the resin fixing holes 118A and 119.

Therefore, in a semiconductor package 200E according to the present embodiment, the lower encapsulant protrusions 230A and 230B may absorb stress both in X and Y-axial directions centering on a region where a semiconductor chip is mounted, thereby reducing the stress.

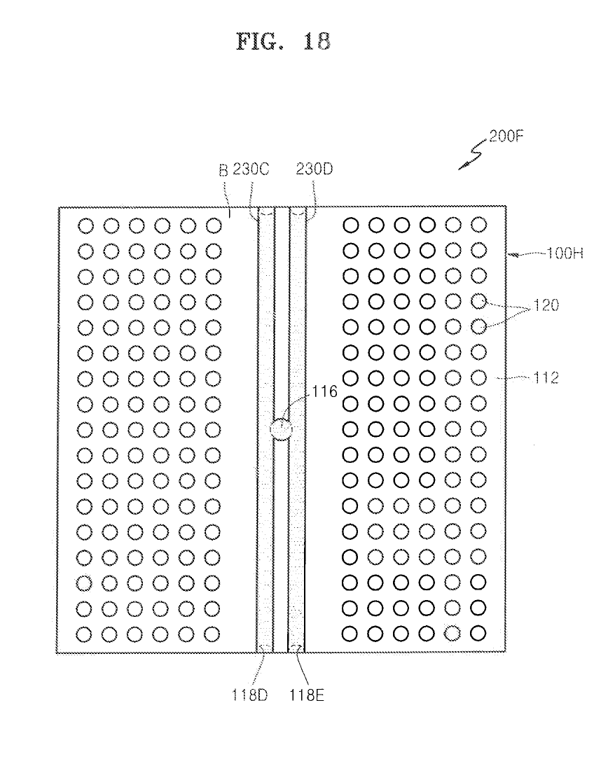

FIG. 18 is a bottom view of a semiconductor package that corresponds to another modified example of FIG. 9C, according to yet another embodiment of the inventive concept.

FIG. 9C shows that the lower encapsulant protrusion 230 has a straight-line shape to connect the resin through hole 116 and the resin fixing holes 118A. However, referring to FIG. 18, the flow of an encapsulant (e.g., an EMC) may be adjusted during a molding process so that two lane-shaped lower encapsulant protrusions 230C and 230D can be formed on a PCB 100h. In this case, two resin fixing holes 118D and 118E may be formed adjacent to each other.

Therefore, the two lower encapsulant protrusions 230C and 230D may simultaneously absorb stress generated within a semiconductor package 200F centering on a region where a semiconductor chip is mounted, thereby reducing the stress.

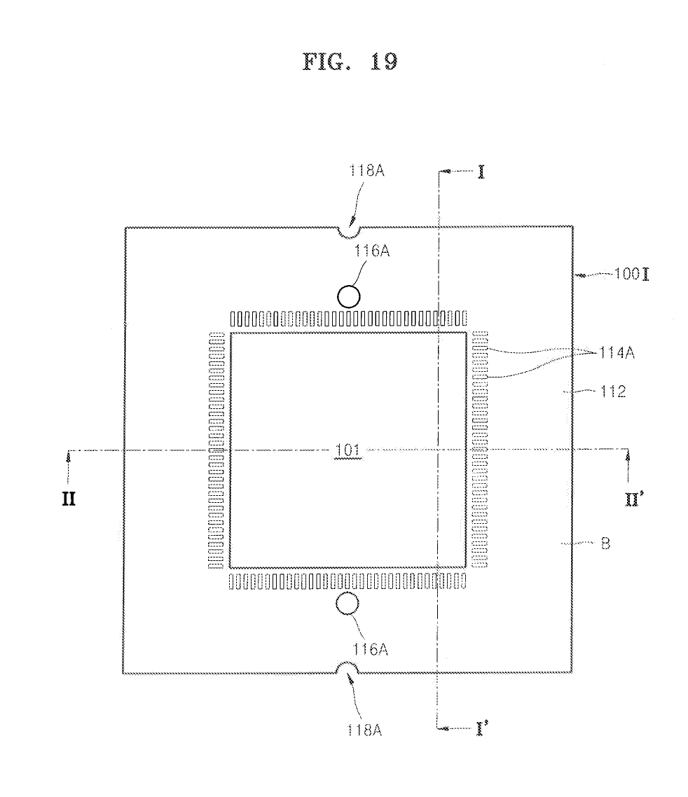

FIG. 19 is a top view of a PCB 100I that corresponds to a modified example of FIG. 2, according to another embodiment of the inventive concept.

All the PCBs 100A to 100H explained thus far with reference to FIGS. 2 through 8 include semiconductor chips mounted thereon using bumps. However, referring to FIG. 19, the resin through hole, the resin fixing holes 118A, and the lower encapsulant protrusion 230 according to the inventive concept may be also applied to semiconductor packages in which semiconductor chips are mounted on PCBs using wires.

FIG. 19 is a top view of a first surface of the PCB 100I as a fine-pitch ball grid array (FBGA) PCB. A chip mounting portion 101 on which a semiconductor chip may be mounted may be prepared in a center of the first surface of the PCB 100I, and first connection pads (e.g., bond fingers) 114A to which wires may be connected may be formed along a vicinity of the chip mounting portion 101. Meanwhile, a resin through hole 116A may be formed outside the chip mounting portion 101 instead of within a central portion of the chip mounting portion 101. Two resin fixing holes 118A may be provided on an outermost edge of the substrate 112.

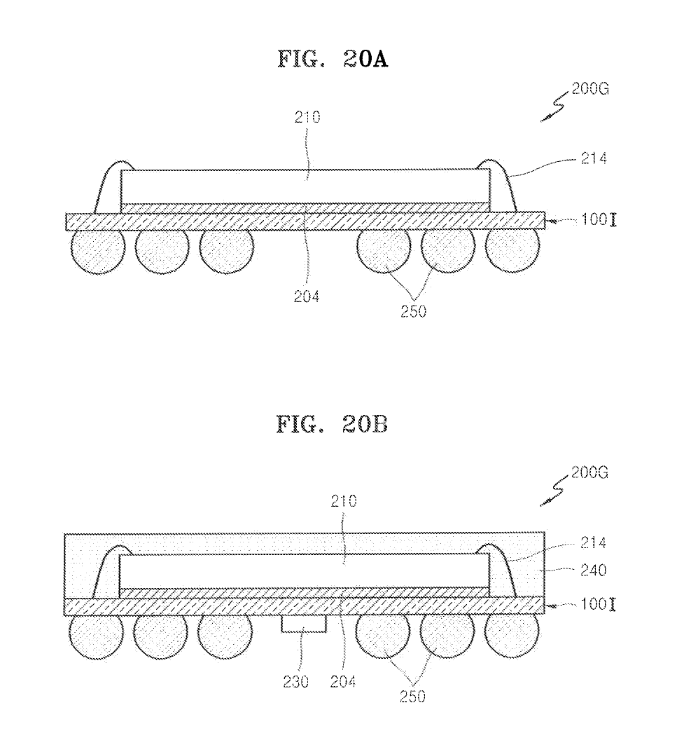

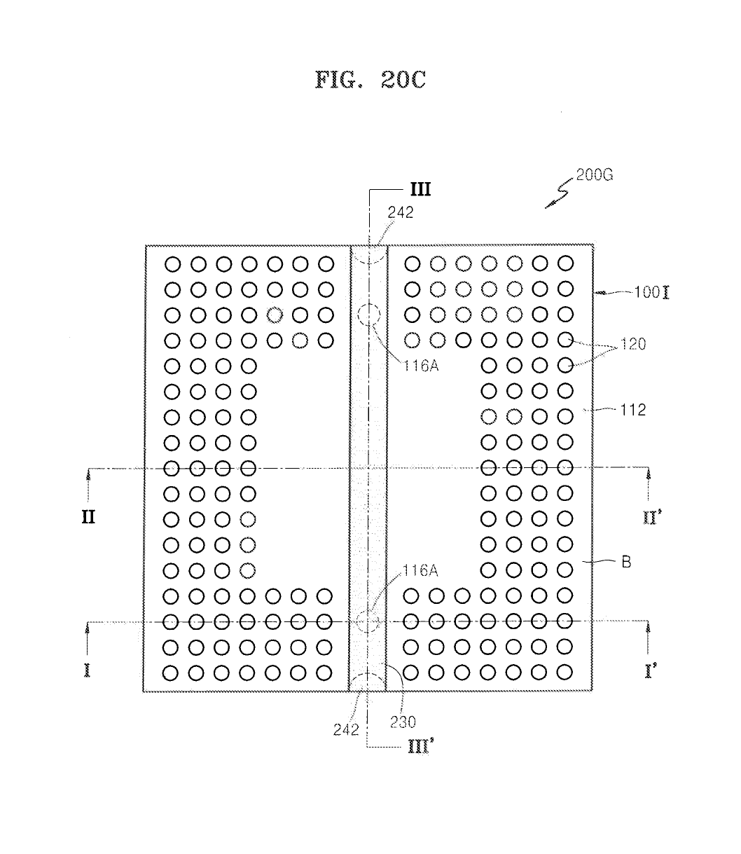

FIGS. 20A and 20B are sectional views taken along a direction I-I′ and II-II′ of FIG. 19, illustrating the PCB of FIG. 19 on which a semiconductor chip is mounted and a molding process is performed.

Referring to FIGS. 20A and 20B, initially, the semiconductor chip 210 may be mounted on the chip mounting portion formed on the PCB 100I using a mounting portion, such as an adhesive tape 204. The semiconductor chip 210 may be mounted in such a way that an active region of the semiconductor chip 210 faces upward. Thereafter, bonding pads prepared on the semiconductor chip 210 may be connected to the bond fingers (refer to 114A in FIG. 19) using wires 214 using a wire bonding process.

Afterwards, the molding process may be performed on the PCB 100I on which the semiconductor chip 210 is mounted. An encapsulant for a semiconductor package used in the molding process may be an MUF encapsulant that may prevent occurrence of void defects at a bonding surface between the semiconductor chip 210 and the PCB 100I. In addition, the MUF encapsulant may include a material that has a relatively low ion content and a relatively low hygroscopic property and is highly adhesive to both the semiconductor chip 210 and the PCB 100I and highly flowable.

Due to the molding process, the upper encapsulant 240 may be formed on a top surface of the PCB 100I and hermetically seal each of the semiconductor chip 210 and the top surface of the PCB 100I. In addition, the encapsulant may flow out to a bottom surface of the PCB 100I through the resin through hole (refer to 116A of FIG. 19) and the resin fixing hole (refer to 118A of FIG. 19) formed in the PCB 100I so that the lower encapsulant protrusion 230 can be on the bottom surface of the PCB 100I.

FIG. 20C is a bottom view of a semiconductor package 200G according to still another embodiment of the inventive concept.

Referring to FIG. 20C, in the semiconductor package 200G according to the present embodiment, the lower encapsulant protrusion 230 may be formed on the bottom surface of a PCB 100I. Also, the second connection pads (e.g., solder ball pads) 120 may be formed in a matrix shape on opposite sides of the lower encapsulant protrusion 230. The lower encapsulant protrusion 230 may be formed as a straight-line type on the bottom surface of the PCB 100I. The resin fixing portion 242 filling the resin fixing hole (refer to 118A in FIG. 19) and the encapsulant filling the resin through hole (refer to 116A in FIG. 19) may surround the PCB 100I as a clip type. The lower encapsulant protrusion 230 including the resin fixing portion 242 filling the resin fixing holes 118A and the encapsulant filling the resin through hole 116A may function to absorb and reduce stress generated within the semiconductor package 200G.

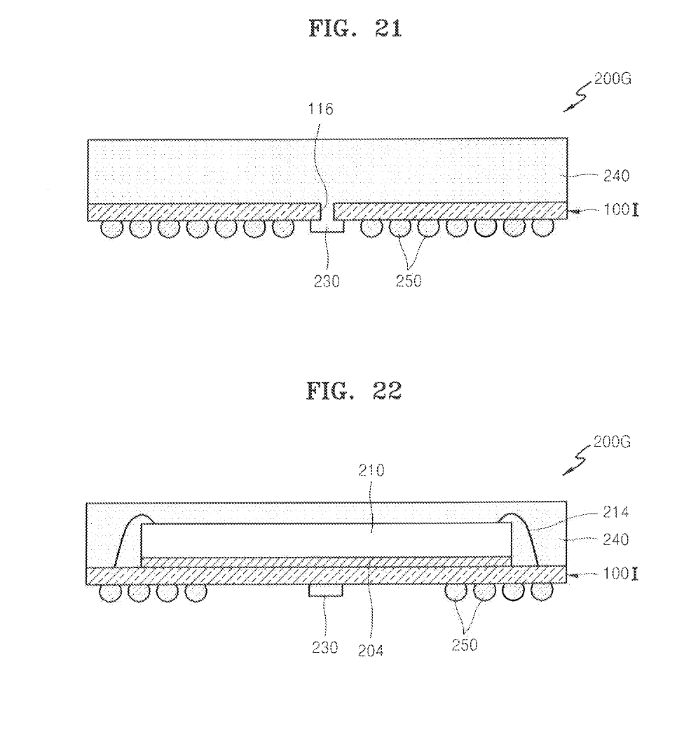

FIG. 21 is a cross-sectional view taken along a direction I-I′ of FIG. 20C, FIG. 22 is a cross-sectional view taken along a direction II-II′ of FIG. 20C, and FIG. 23 is a cross-sectional view taken along a direction III-III′ of FIG. 20C.

Referring to FIGS. 21 through 23, initially, the solder balls 250 may be adhered to the second connection pads 120 disposed on the bottom surface of the PCB 100I. The formation of the solder balls 250 may be performed using a reflow soldering process. Meanwhile, the lower encapsulant protrusion 230 may have a smaller height than the solder balls 250. Otherwise, the formation of the solder balls 250 may be hampered by the lower encapsulant protrusion 230 when the semiconductor package 200G is mounted on a mother board of an electronic device.

Referring to the cross-sectional view of FIG. 21 taken along the direction I-I′ of FIG. 20C, the lower encapsulant protrusion 230 formed through the resin through hole 116A may bisect the PCB 100I in a lateral direction. Accordingly, when stress is generated in the semiconductor package 200G, the lower encapsulant protrusion 230 configured to bisect the PCB 100I through the resin through hole 116 may absorb the stress from a central portion of the PCB 100I. The stress may be generated by expanding and contracting the bonding surface between the semiconductor chip 210 and the PCB 100I due to an external temperature variation.

Referring to the cross-sectional view of FIG. 23 taken along the direction III-III′ of FIG. 20C, the lower encapsulant protrusion 230 may absorb the stress from both a portion where the resin through hole 116A is formed and an edge portion where the resin fixing holes 118A is formed. Accordingly, stress applied to the bonding surface between the semiconductor chip 210 and the PCB 100I may be reduced.

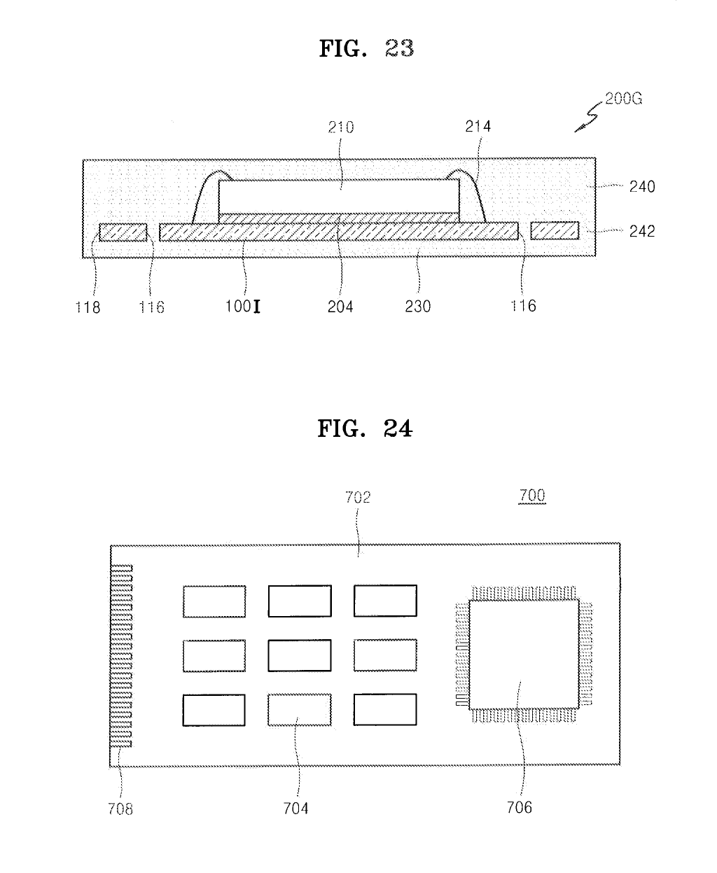

FIG. 24 is a top view of a package module 700 according to an embodiment of the inventive concept.

Referring to FIG. 24, the package module 700 may include a module substrate 702 having external connection terminals 708, a semiconductor package 704, and a quad flat package (QFP) 706 mounted on the module substrate 702. The semiconductor package 704 may include any of the semiconductor packages according to the embodiments of the inventive concept. The package module 700 may be connected to an external electronic device by the external connection terminals 708.

FIG. 25 is a schematic diagram of a memory card 800 according to an embodiment of the inventive concept.

Referring to FIG. 25, the memory card 800 may include a controller 820 and a memory device 830 disposed in a housing 810. The controller 820 and the memory device 830 may exchange electrical signals with each other. For example, the controller 820 and the memory device 830 may exchange data with each other in response to commands. Thus, the memory card 800 may store data in the memory device 830 or externally transmit data from the memory device 830.

The controller 820 and/or the memory device 830 may include at least one of semiconductor devices or semiconductor packages according to the embodiments of the inventive concept. The memory card 800 may be used as a data storing medium of various portable apparatuses. For example, the memory card 800 may include a multimedia card (MMC) or a secure digital (SD) card.

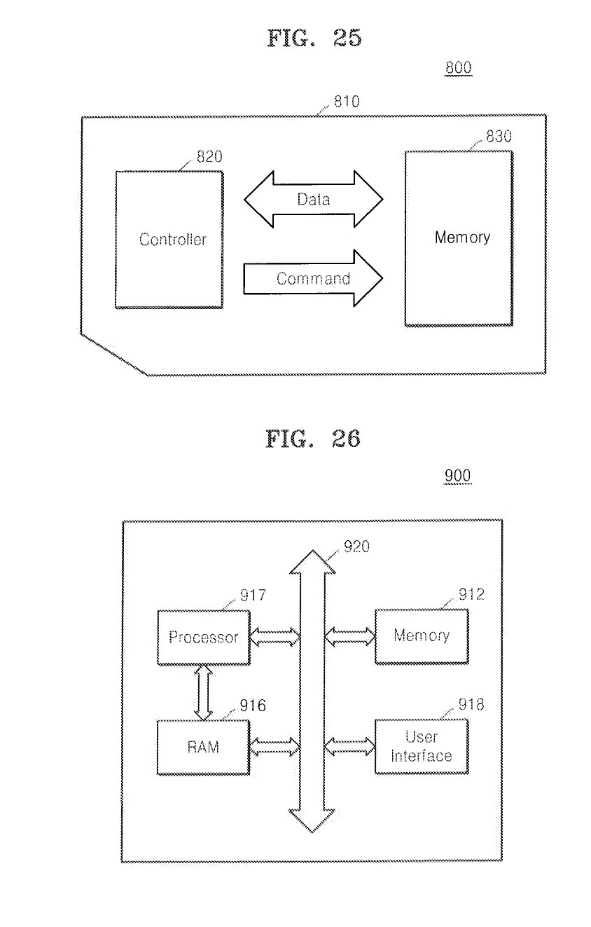

FIG. 26 is a block diagram of an electronic system 900 according to an embodiment of the inventive concept.

Referring to FIG. 26, the electronic system 900 may include at least one of the semiconductor devices or semiconductor packages according to the embodiments of the inventive concept. The electronic system 900 may include a mobile device or a computer. For example, the electronic system 900 may include a memory system 912, a processor 917, a random access memory (RAM) device 916, and a user interface 918 that may communicate data with one another through a bus 920. The processor 917 may serve to execute a program or control the electronic system 900. The RAM device 916 may be used as an operating memory of the processor 917. For example, each of the processor 917 and the RAM device 916 may be included in the semiconductor device or semiconductor package according to the embodiments of the inventive concept. Furthermore, the processor 917 and the RAM device 916 may be included in a single package. The user interface 918 may be used to input or output data into or from the electronic system 900. The memory system 912 may store a code required for operating the processor 917, data processed by the processor 917, or externally input data. The memory system 912 may include a controller and a memory device and have substantially the same construction as the memory card 800 of FIG. 25.

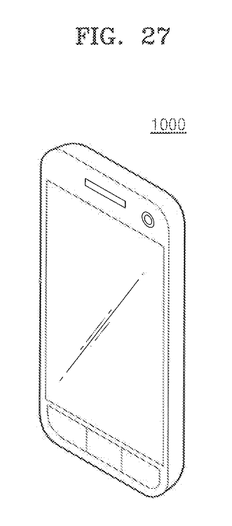

The electronic system 900 of FIG. 26 may be applied to an electronic control device of various electronic apparatuses. For example, FIG. 27 illustrates that the electronic system 900 of FIG. 26 is applied to a mobile phone 1000. In addition, the electronic system 900 of FIG, 26 may be applied to portable laptop computers, MP3 players, navigation systems, solid state disks (SSDs), automobiles, or household appliances.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A printed circuit board (PCB) for a semiconductor package with improved solder joint reliability, comprising:
a substrate for a semiconductor package including a metal interconnection disposed therein, the substrate having a first surface and a second surface disposed opposite to the first surface;
a first connection pad disposed on the first surface of the substrate and connected to a semiconductor chip;
a second connection pad disposed on the second surface of the substrate and configured to outwardly expand functionality of the semiconductor chip;
a resin through hole formed through the substrate in a central portion of the substrate; and
at least one resin fixing hole formed through the substrate outside the central portion of the substrate.

2. The PCB of claim 1, wherein the resin through hole is formed in a region of the first surface of the substrate where a semiconductor chip is mounted.

3. The PCB of claim 1, wherein the resin through hole is formed outside a region of the first surface of the substrate where the semiconductor chip is mounted.

4. The PCB of claim 1, wherein the first connection pad is one of a wire and a bump.

5. The PCB of claim 1, wherein the second connection pad is connected to a solder ball.

6. The PCB of claim 2, wherein the substrate is an embedded type substrate in which the semiconductor chip is inserted.

7. The PCB of claim 1, further comprising an additional resin fixing hole disposed between the resin through hole and the resin fixing hole.

8. The PCB of claim 1, wherein the resin fixing hole has a size equal to or greater than that of the resin through hole.

9. A semiconductor package with improved solder joint reliability, comprising:
a printed circuit board (PCB) for a semiconductor package including a resin through hole disposed in a central portion thereof and at least one resin fixing hole disposed in an outermost edge thereof;
a semiconductor chip connected to a first connection pad disposed on a first surface of the PCB by a bump;
an upper encapsulant configured to hermetically seal the first surface of the PCB and the semiconductor chip; and
a lower encapsulant protrusion configured to extend to a second surface of the PCB through the resin through hole and the resin fixing hole disposed in the first surface of the PCB.

10. The semiconductor package of claim 9, wherein the resin fixing hole has one selected from the group consisting of a semicircular shape, a rectangular shape, and a semielliptical shape.

11. The semiconductor package of claim 9, further comprising a solder ball connected to a conductive pad disposed on the second surface of the PCB,
wherein the solder ball has a greater height than the lower encapsulant protrusion.

12. The semiconductor package of claim 9, wherein the semiconductor chip is a multi-stack structure of at least two semiconductor chips.

13. The semiconductor package of claim 12, wherein the bump is a through silicon via (TSV) configured to connect connection terminals of the at least two semiconductor chips with one another.

14. The semiconductor package of claim 9, wherein the PCB further comprises an additional resin fixing hole disposed between the resin through hole and the resin fixing hole.

15. The semiconductor package of claim 9, wherein the lower encapsulant protrusion has a straight-line shape and is connected to the at least one resin fixing hole across the resin through hole disposed in the central portion of the PCB.

16. The semiconductor package of claim 9, wherein the lower encapsulant protrusion has a cross shape formed in such a way that the resin through hole of the PCB is disposed at an intersection of the lower encapsulant protrusion.

17. A semiconductor package with improved solder joint reliability, comprising:
a printed circuit board (PCB) for a semiconductor package including a resin through hole disposed in a central portion thereof and at least one resin fixing hole disposed in an outermost edge thereof;
a semiconductor chip mounted on a first surface of the PCB;
a wire configured to electrically connect a first connection pad disposed on the first surface of the PCB to the semiconductor chip;
an upper encapsulant configured to hermetically seal the first surface of the PCB, the semiconductor chip, and the wire; and
a lower encapsulant protrusion configured to extend to a second surface of the PCB through the resin through hole and the resin fixing hole disposed in the first surface of the PCB.

18. The semiconductor package of claim 17, wherein the resin through hole is formed outside a region where the semiconductor chip is mounted.

19. The semiconductor package of claim 17, further comprising a solder ball connected to a conductive pad disposed on the second surface of the PCB.

20. The semiconductor package of claim 19, wherein the lower encapsulant protrusion has a smaller height than the solder ball.

21. A semiconductor package, comprising:
a printed circuit board (PCB) including:
first connection pads disposed on a first surface thereof and connected to a semiconductor chip,
second connection pads disposed on a second surface thereof opposite the first surface and configured to outwardly expand functionality of the semiconductor chip,
a resin through hole formed through the PCB in a central portion thereof, and
at least one resin fixing hole formed therethrough outside the central portion thereof;
an upper encapsulant disposed on the first surface of the PCB to hermetically seal the semiconductor chip and the first surface of the PCB; and
a lower encapsulant protrusion extending through the resin through hole and the at least one resin fixing hole and along a portion of the second surface.

22. The semiconductor package of claim 21, wherein the portion of the second surface in which the lower encapsulant extends is a first straight line extending from a first end of the PCB to a second end of the PCB opposite the first end, and the resin through hole and the at least one resin fixing hole are disposed along the same first straight line.

23. The semiconductor package of claim 22, wherein the lower encapsulant further extends along a second straight line from a third end of the PCB to a fourth end of the PCB opposite the third end such that the first straight line and the second straight line form a cross shape, the resin through hole and the at least one resin fixing hole also being disposed along the same second straight line.

24. The semiconductor package of claim 23, wherein the at least one resin fixing hole includes a plurality of resin fixing holes each disposed between the resin through hole and an outermost edge of the PCB.

25. The semiconductor package of claim 22, wherein the lower encapsulant protrusion is formed to have an “I” shape such that perpendicular cross sections are provided at each end of the first straight line such that the resin through hole more effectively absorbs stress generated at a bonding surface between the PCB and the semiconductor chip.

26. The semiconductor package of claim 21, wherein the upper encapsulant and the lower encapsulant are formed of an epoxy mold compound (EMC).

27. The semiconductor package of claim 21, wherein:
the second connection pads are formed of solder ball pads serving as conductive elements; and
the first connection pads are formed of bumps serving as conductive elements to which the semiconductor chip is connected.

28. The semiconductor package of claim 21, wherein the at least one resin fixing hole is formed to a width greater than that of the resin through hole.

29. A method of forming a semiconductor package, comprising:
connecting a semiconductor chip on a printed circuit board (PCB) via first connection pads on a first surface of the PCB;
disposing second connection pads on the PCB on a second surface thereof opposite the first surface;
filling the space between the semiconductor chip and the PCB with a molded underfill resin such that the resin flows out to the second surface of the PCB through a resin through hole disposed at a center portion of the PCB and at least one resin fixing hole disposed outside the central portion of the PCB to form a lower encapsulant protrusion along the second surface of the PCB; and
performing a molding process to hermetically seal the semiconductor chip and the first surface of the PCB.

30. The method of claim 29, wherein the molding process is formed of the same material as the molded underfill resin.

31. The method of claim 28, wherein the lower encapsulant protrusion is formed within a recess region on the second surface where a lower mold of a molding apparatus is mounted.
